(19) United States
(12) Patent Application Publication
(10) Pub. No.: US 2025/0180808 A1
(43) Pub. Date: Jun. 5, 2025

(54) ULTRA LOW LOSS SILICON NITRIDE BASED WAVEGUIDE

(71) Applicant: PSIQUANTUM CORP., Palo Alto, CA (US)

(72) Inventors: Ann MELNICHUK, Rio Rancho, NM (US); Vimal KAMINENI, Mechanicville, NY (US)

(21) Appl. No.: 18/840,438

(22) PCT Filed: Feb. 22, 2023
(86) PCT No.: PCT/US2023/013623

§ 371 Date: Aug. 21, 2024

Related U.S. Application Data
(60) Provisional application No. 63/313,025, filed on Feb. 23, 2022.

(51) Int. Cl. G02B 6/132; G02B 6/12; G02B 6/122; G02B 6/136

(52) U.S. Cl. CPC G02B 6/132; G02B 6/122; G02B 6/136; G02B 2006/12061

(57) ABSTRACT

A method of making a waveguide includes providing a first portion of a cladding located over a substrate. forming a silicon nitride core over the first portion of the cladding using a deuterated silane source in a low-pressure chemical vapor deposition process, and forming a second portion of the cladding over the silicon nitride core.

### TECHNICAL FIELD

The present disclosure generally relates to optical devices and more particularly to waveguides and methods of making thereof.

### BACKGROUND

An optical waveguide includes a core surrounded by a cladding having a lower refractive index than the core. Some silicon nitride cores suffer from undesirable optical losses. Thus, a low loss silicon nitride core is desired.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, or characteristic included in at least one implementation of the inventive subject matter. Thus, phrases such as “in one embodiment” or “in an alternate embodiment” appearing herein describe various embodiments and implementations of the inventive subject matter, and do not necessarily all refer to the same embodiment. However, they are also not necessarily mutually exclusive. To easily identify the discussion of any element or act, the most significant digit or digits in a reference number refer to the figure (“FIG.”) number in which that element or act is first introduced.

FIG. 1A is a schematic diagram illustrating an optical switch according to an embodiment of this disclosure.

FIG. 1B is a system diagram illustrating incorporation of an electro-optic switch with a cryostat into a hybrid quantum computing system, according to some embodiments.

FIG. 2 shows an example manufacturing system for manufacturing ultra-low loss hydrogen-free silicon nitride photonic components, in accordance with some example embodiments.

FIG. 3A and 3B show an optical structure with an ultra-low loss silicon nitride waveguide, in accordance with some example embodiments.

FIG. 4 shows a transmittance graph, in accordance with some example embodiments.

FIG. 5 shows a flow diagram of a method for manufacturing hydrogen free silicon nitride waveguides, in accordance with some example embodiments.

Descriptions of certain details and implementations follow, including a description of the figures, which may depict some or all the embodiments described below, as well as discussing other potential embodiments or implementations of the inventive concepts presented herein. An overview of embodiments of the disclosure is provided below, followed by a more detailed description with reference to the drawings.

### DETAILED DESCRIPTION

In the following description, for the purposes of explanation, numerous specific details are set forth to provide an understanding of various embodiments of the inventive subject matter. It will be evident, however, to those skilled in the art, that embodiments of the inventive subject matter may be practiced without these specific details. In general, well-known instruction instances, structures, and techniques are not necessarily shown in detail.

According to an aspect of the present disclosure, a method of making a waveguide includes providing a first portion of a cladding located over a substrate, forming a silicon nitride core over the first portion of the cladding using a deuterated silane source in a low-pressure chemical vapor deposition (“LPCVD”) process, and forming a second portion of the cladding over the silicon nitride core.

According to another aspect of the present disclosure, a waveguide comprises a silicon nitride core, and a cladding surrounding the core, the cladding having a lower refractive index than the core. The silicon nitride core contains a deuterium concentration detectable by Fourier transform infrared (“FTIR”) spectroscopy. The silicon nitride core is completely hydrogen free or contains a hydrogen concentration below detection limit of at least one of electron energy loss spectroscopy (“EELS”), X-ray photoelectron spectroscopy (“XPS”) or secondary-ion mass spectrometry (“SIMS”). The silicon nitride core exhibits at least one of a maximum difference in loss value between wavelengths of 1520 nm and 1550 nm of 0.01 dB/cm or less, or an average loss value between wavelengths of 1500 nm and 1600 nm of 0.2 dB/cm or less.

The presence of hydrogen in a silicon nitride waveguide core can cause optical losses at wavelengths between 1500 and 1600 nm. Silane can be used as the silicon source (e.g., precursor) during the core chemical vapor deposition process, however a significant amount of hydrogen (e.g., above the detectable concentration by XPS, EELS, and/or SIMS) may be incorporated into the silicon nitride core. The detectable concentration of hydrogen in silicon nitride by XPS is 5 atomic % or greater, by EELS is 0.5 atomic % or greater, and by SIMS is 10¹⁷ atoms/cm³ or greater (e.g., at least 10¹⁷ hydrogen atoms/cm³ are incorporated into silicon nitride by using a silane precursor).

Furthermore, even if deuterated silane (SiD₄) instead of silane (SiH₄) is used as the silicon source in an electron cyclotron resonance (ECR) plasma enhanced chemical vapor deposition (PECVD) of a silicon nitride waveguide core, the propagation losses from a linear approximation of such silicon nitride waveguide core can be 0.55 dB/cm and about 0.47 dB/cm, respectively, at 1530 nm and 1550 nm, respectively which may not satisfy the operating parameters of system photonic designs. Further, the loss across the C-band range of such silicon nitride core is non uniform and further uniformity may be required by a given photonic design. The use of the PECVD process at low temperatures (e.g., 400 to 600 degrees) can result in higher than desired losses.

To address the foregoing, and in accordance with some example embodiments, a silicon nitride core is deposited using a low-pressure chemical vapor deposition (“LPCVD”) process using a deuterated source (e.g., precursor). The LPCVD process is a higher temperature process than PECVD and may be conducted at a temperature of 800 degrees Celsius to 1150 degrees Celsius, such as 800 to 950 degrees Celsius. By depositing the silicon nitride core of a waveguide using the LPCVD process using a deuterated silane source lower losses are achieved as compared to PECVD based approaches

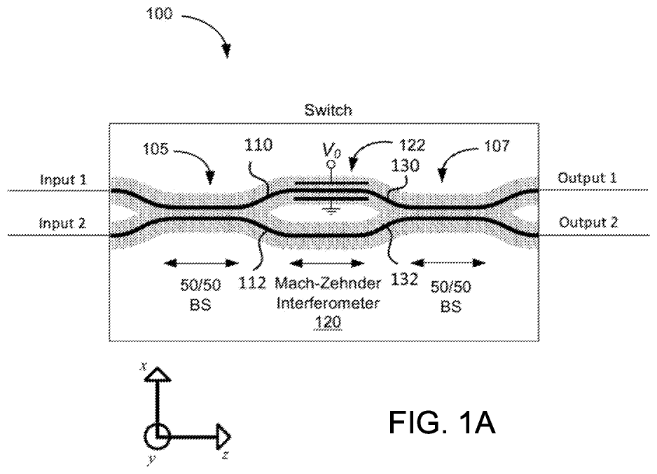

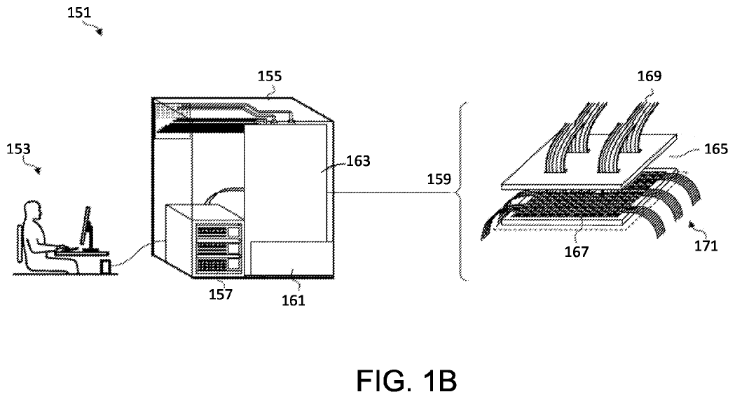

FIG. 1A is a schematic diagram illustrating an optical switch according to an embodiment of this disclosure. The example switch is a switch that can be implemented in a high-performance computing system (e.g., as shown in FIG. 1B) that uses ultra-low loss waveguides for processing one or more photons (e.g., single photons, entangled photons). Referring to FIG. 1A, electro-optic switch 100 includes two inputs: Input 1 and Input 2 as well as two outputs: Output 1 and Output 2. As an example, the inputs and outputs of the electro-optic switch 100 can be implemented as optical waveguides operable to support single mode or multimode optical beams. As an example, the electro-optic switch 100 can be implemented as a Mach-Zehnder interferometer integrated with a set of 50/50 beam splitters 105 and 107, respectively. As illustrated in FIG. 1A, Input 1 and Input 2 are optically coupled to a first 50/50 beam splitter 105, also referred to as a directional coupler, which receives light from the Input 1 or Input 2 and, through evanescent coupling in the 50/50 beam splitter, directs 50% of the input light from Input 1 into waveguide 110 and 50% of the input light from Input 1 into waveguide 112. Concurrently, first 50/50 beam splitter 105 directs 50% of the input light from Input 2 into waveguide 110 and 50% of the input light from Input 2 into waveguide 112. Considering only input light from Input 1, the input light is split evenly between waveguides 110 and 112.

Mach-Zehnder interferometer 120 includes phase adjustment section 122. Voltage V0 can be applied across the waveguide in phase adjustment section 122 such that it can have an index of refraction in phase adjustment section 122 that is controllably varied. Because light in waveguides 110 and 112 still have a well-defined phase relationship (e.g., they may be in-phase, 180° out-of-phase, etc.) after propagation through the first 50/50 beam splitter 105, phase adjustment in phase adjustment section 122 can introduce a predetermined phase difference between the light propagating in waveguides 130 and 132. As will be evident to one of skill in the art, the phase relationship between the light propagating in waveguides 130 and 132 can result in output light being present at Output 1 (e.g., light beams are in-phase) or Output 2 (e.g., light beams are out of phase), thereby providing switch functionality as light is directed to Output 1 or Output 2 as a function of the voltage V0 applied at the phase adjustments section 122. Although a single active arm is illustrated in FIG. 1A, it will be appreciated that both arms of the Mach-Zehnder interferometer can include phase adjustment sections.

As illustrated in FIG. 1A, electro-optic switch technologies, in comparison to all-optical switch technologies, utilize the application of the electrical bias (e.g., V0 in FIG. 1A) across the active region of the switch to produce optical variation. The electric field and/or current that results from application of this voltage bias results in changes in one or more optical properties of the active region, such as the index of refraction or absorbance.

Although a Mach-Zehnder interferometer implementation is illustrated in FIG. 1A, embodiments of this disclosure are not limited to this switch architecture and other phase adjustment devices are included within the scope of this disclosure, including ring resonator designs, Mach-Zehnder modulators, generalized Mach-Zehnder modulators, and the like. One of ordinary skill in the art would recognize many variations, modifications, and alternatives.

In some embodiments, the optical phase shifter devices described with respect to FIG. 1A above may be utilized within a quantum computing system, such as the hybrid quantum computing system shown in FIG. 1B. Alternatively, these optical phase shifter devices may be used in other types of optical systems. For example, other computational, communication, and/or technological systems may utilize photonic phase shifters to direct optical signals (e.g., single photons or continuous wave (CW) optical signals) within a system or network, and phase shifter architectures described herein may be used within these systems, in various embodiments.

FIG. 1B is a system diagram illustrating incorporation of an electro-optic switch with a cryostat into a hybrid quantum computing system, according to some embodiments. To operate at low temperatures, for example liquid helium temperatures, embodiments of this disclosure integrate the electro-optic switches discussed herein (e.g., see FIG. 1A) into a system that includes cooling systems. Thus, embodiments of this disclosure provide an optical phase shifter that may be used within a hybrid computing system of the type illustrated in FIG. 1B. The hybrid computing system 151 includes a user interface device 153 that is communicatively coupled to a hybrid quantum computing (QC) sub-system 155. The user interface device 153 may be any type of user interface device, for example, a terminal including a display, keyboard, mouse, touchscreen, and the like. In addition, the user interface device may itself be a computer such as a personal computer (PC), laptop, tablet computer, etc.

In some embodiments, the user interface device 153 provides an interface with which a user can interact with the hybrid QC subsystem 155. For example, the user interface device 153 may run software, such as a text editor, an interactive development environment (IDE), command prompt, graphical user interface, and the like so that the user can program, or otherwise interact with, the QC subsystem to run one or more quantum algorithms. In other embodiments, the QC subsystem 155 may be pre-programmed and the user interface device 153 may simply be an interface where a user can initiate a quantum computation, monitor the progress, and receive results from the hybrid QC subsystem 155. Hybrid QC subsystem 155 may further include a classical computing system 157 coupled to one or more quantum computing chips 159. In some examples, the classical computing system 157 and the quantum computing chip 159 can be coupled to other electronic components, e.g., pulsed pump laser 161, microwave oscillators, power supplies, networking hardware, etc.

The quantum computing chips 159 may be housed within a cryostat, for example, cryogenic device 163. In some embodiments, each of the quantum computing chips 159 can include one or more constituent chips, e.g., hybrid electronic chip 165 and integrated photonics chip 167. The photonics chip 167 may include the electro-optic switch 100 (e.g., an interferometer) shown in FIG. 1A. Signals can be routed on-and off-chip any number of ways, e.g., via optical interconnects (e.g., optical fiber bundles) 169 and via other electronic interconnects 171.

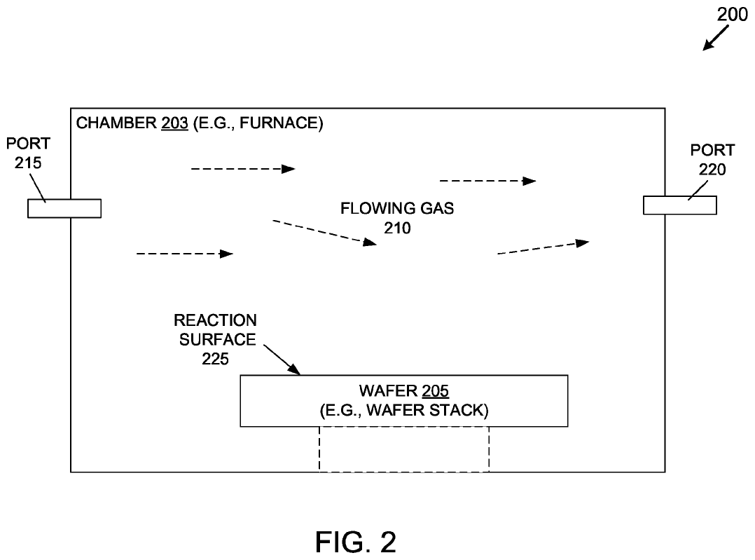

FIG. 2 shows an example manufacturing system 200 for manufacturing ultra-low loss hydrogen-free silicon nitride photonic components, in accordance with some example embodiments. As illustrated, a wafer 205 (e.g., silicon wafer) is positioned in a chamber 203. The pressure, temperature, and gas composition provided into the chamber 203 is controlled to perform vapor deposition. For example, the chamber 203 can be configured to implement low-pressure chemical vapor deposition (e.g., the chamber 203 is an LPCVD chamber). At a high level, PECVD implements deposition using electrodes that are charged to create a plasma in a deposition chamber. In contrast, LPCVD does not implement plasma as PECVD does, and LPCVD may implement higher temperatures than PECVD (e.g., 850 to 1200 degrees Celsius). In some example embodiments, the chamber 203 is configured to implement low pressure chemical vapor deposition to form ultra-low loss components. In some example embodiments, the chamber 203 is a furnace for LPCVD based application of gases to stacks of wafers. In those example embodiments, the wafer 205 is placed in a vertical stack of wafers and heaters (e.g., not depicted in FIG. 2) heat the chamber 203 for the LPCVD processes.

In the illustrated example, a first port 215 (e.g., inlet) inputs one or more gases into the chamber which form a flowing gas stream that flows through the chamber 203 and exits through a second port 220 (e.g., outlet). Although only two ports are illustrated in the example of FIG. 2, it is appreciated that multiple ports (e.g., multiple inlet ports, multiple outlet ports) can be implemented to input and remove source gases in the manufacturing system 200, in accordance with some example embodiments. In some example embodiments, one or more precursors (e.g., ammonia, deuterated silane) are input into the chamber 203 and a chemical reaction occurs on a reaction surface 225 of the wafer 205 to form a thin film on the wafer 205, such as a silicon nitride layer as discussed in further detail below. The deposited thin film may then be further processed (e.g., heated, patterned) and additional components (e.g., semiconductor components) can be added to the wafer 205 to form high performance photonics devices with ultra-low loss hydrogen-free waveguides for light propagation (e.g., single photon processing, quantum light processing).

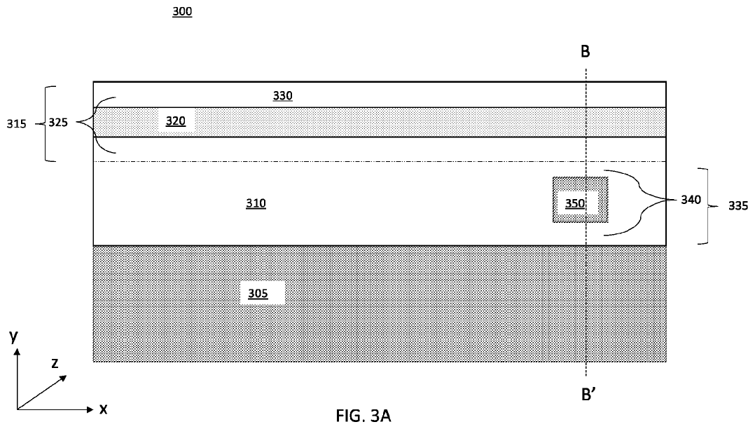

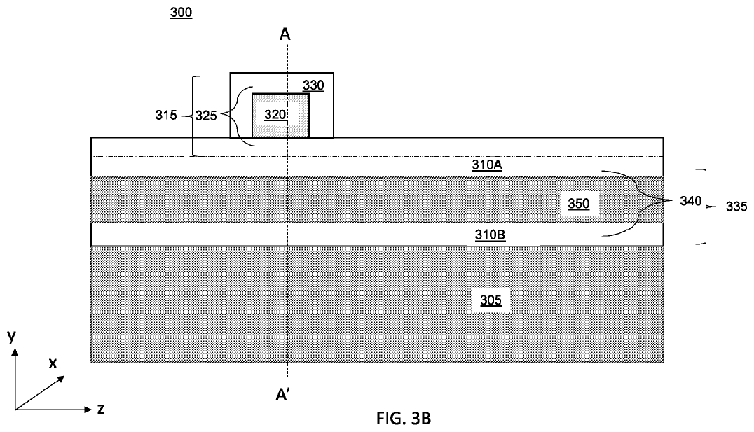

FIGS. 3A and 3B show example embodiments of ultra-low loss silicon nitride waveguides that are implemented in quantum light photonics information processing systems, such as a highly sensitive photon detector or a switch (e.g., electro-optic switch 100, FIG. 1A) in the photonic chip 167 (e.g., silicon photonics). FIG. 3B is a cross-sectional view of an optical structure 300 (e.g., portion of a photonic integrated circuit) along a B-B′ plane in FIG. 3A; that is, the B-B′ plane is a slice along the Y-Z plane in three dimensions, X, Y, and Z. Further, FIG. 3A is a cross-sectional view of the same optical structure along an A-A′ plane in FIG. 3A; that is, the A-A′ plane is a slice down the Y-X plane in the three dimensions.

With reference to FIG. 3A, and in accordance with some example embodiments, a first waveguide 315 comprises a silicon nitride core 320, and a cladding 325 surrounding the silicon nitride core 320. In some example embodiments, the material of the cladding 325 has a lower refractive index than the material of the silicon nitride core 320. According to one embodiment, a method of making the waveguide 315 comprises depositing a first portion (e.g., lower portion) of a cladding 325 located over a substrate 305 (e.g., silicon substrate), forming the silicon nitride core 320 over the first portion of the cladding 325 using a deuterated silane (SiD₄) source in a low pressure chemical vapor deposition (“LPCVD”) process, and forming a second portion (e.g., upper portion) of the cladding 325 over the silicon nitride core 320.

In one embodiment, an ammonia source gas (e.g., first precursor) is used as the nitrogen source in addition to the SiD₄ gas used as the silicon source gas (e.g., second precursor) during the LPCVD process to form the silicon nitride core 320. In one embodiment, the LPCVD process is conducted at a temperature between 800 degrees Celsius and 1150 degrees Celsius without using a plasma.

In another embodiment, the LPCVD process uses a hydrogen free silicon source (e.g., silicon source free of atomic hydrogen, H) and a deuterated nitrogen source to deposit the silicon nitride core 320. In this embodiment, any suitable deuterated nitrogen source is used as the hydrogen free nitrogen source during the LPCVD process. The deuterated nitrogen source may comprise deuterated ammonia (ND₃), where D is deuterium. Thus, the hydrogen atoms are replaced with deuterium atoms in the deuterated ammonia. In alternative embodiments, an organic deuterated nitrogen containing gas, such as a deuterated amine gas may be used as the deuterated nitrogen source. The organic deuterated nitrogen containing gas may have a formula NDa(CxDy)b, where N is nitrogen, C is carbon, D is deuterium, and a, b, x and y comprise integers having independent values between 0 and 10, such as between and 1 and 6. For example, for a=0, x=2, y=6 and b=3, the organic deuterated ammonia gas may have a formula N(C₂D₆)₃. Thus, in one embodiment, a deuterated methylamine (i.e., CD₅N which may also be written as ND₃(CD₂) in the above notation) or a deuterated ethylamine (i.e., C₂D₇N which may also be written as ND₃(CD₂)₂ in the above notation) may be used in which the hydrogen atoms are replaced with deuterium atoms.

In one embodiment, any suitable hydrogen free silicon source is used in combination with the deuterated nitrogen source. In one embodiment, the hydrogen free silicon source comprises a silicon halide gas, such as silicon tetrachloride (SiCl₄). In another embodiment, the hydrogen free silicon source comprises deuterated silane (SiD₄). In another embodiment, the hydrogen free silicon source comprises a stable deuterated silicon halide gas, such as SiD₃Cl₁, SiD₂Cl₂ (deuterated dichlorosilane) or SiD₁Cl₃. In another embodiment, the hydrogen free silicon source comprises a deuterated organic silane gas, such as deuterated methylsilane or deuterated ethylsilane in which hydrogen atoms are substituted with deuterium atoms. In another embodiment, the hydrogen free silicon source comprises a halosilane gas, which may have a formula SiDa(CxDy)bZc, where Si is silicon, C is carbon, D is deuterium, Z is any halogen (e.g., F, Cl, Br and/or I), and a, b, c, x and y comprise integers having independent values between 0 and 10, such as between and 1 and 6.

In one embodiment, forming the silicon nitride core 320 comprises depositing a silicon nitride layer on the underlying first silicon oxide layer 310 located over the substrate 305 using the LPCVD process, and patterning the silicon nitride layer into the silicon nitride core 320. In some example embodiments, the patterning is implemented by forming a masking layer (e.g., photoresist or e-beam resist), followed by photolithographic or electron beam patterning of the masking layer into the desired shape, and then etching the masked silicon nitride layer to form the silicon nitride core 320. In some example embodiments, the silicon nitride core has a height of 200 nm to 4000 nm, and a width of 200 nm to 4000 nm. The masking layer may be removed after the etching by ashing or another suitable process. In some example embodiments, the second (e.g., upper) portion of the cladding 325 is then formed by depositing a second silicon oxide layer 330 over the silicon nitride core 320 after patterning the silicon nitride layer. Thus, in one embodiment, the cladding 325 comprises a silicon oxide cladding. In other embodiment, other cladding materials, such as silicon oxynitride may be used.

In one embodiment, the first (e.g., lower) portion of the cladding 325 comprises the first silicon oxide layer 310 located over the substrate 305. The substrate 305 may comprise any suitable substrate, such as a semiconductor (e.g., silicon wafer), insulating or conductive substrate. In one embodiment, the LPCVD process may comprise a front end of the line (FEOL) process. In other words, the LPCVD process may be performed prior to forming semiconductor devices, such as transistors, which are damaged at temperatures above 700 degrees Celsius.

In one embodiment, a semiconductor component is located over the substrate 305 prior to deposition of the silicon nitride core 320. The semiconductor component should comprise a component which can withstand LPCVD temperatures in a specific range (e.g., 750 to 1150 degrees Celsius, such as 750 to 850 degrees Celsius) without being significantly damaged. In one embodiment, the semiconductor component comprises a second waveguide 335. In the view of FIG. 3A the second waveguide 335 extends in and out of FIG. 3A; in the view of FIG. 3B, the second waveguide 335 extends across horizontally across FIG. 3B and the first waveguide 315 extends in-and-out of FIG. 3B.

Continuing with reference to FIG. 3A, and in accordance with some example embodiments, the second waveguide 335 comprises a silicon core 350 that is embedded in the first silicon oxide layer 310 and located below the silicon nitride core 320. In this way, the first silicon oxide layer 310 functions as the cladding 340 for the silicon core 350 of the second waveguide 335 and as the lower portion of the cladding 325 of the silicon nitride core 320 of the waveguide 315. As such, in the optical structure 300, the two waveguides (first waveguide 315, second waveguide 335) may share portion of a same portion of cladding. As illustrated in FIGS. 3A and FIG. 3B and in accordance with some example embodiments, the silicon core 350 extends non-parallel relative to the silicon nitride core 320 (e.g., the silicon core 350 extends perpendicular to the silicon nitride core 320 in the electro-optic switch 100). In some example embodiments, an optical device comprises the waveguide 315, the substrate 305, and a semiconductor component (e.g., second waveguide 335) located between the substrate 305 and the silicon nitride core 320. Although a silicon waveguide is discussed here as an example component that undergoes the LPCVD processing which forms the silicon nitride layer, it is appreciated that in some example embodiments other types of components (e.g., phase shifters, heaters, temperature sensors, barium titanate based phase shifters) are embedded in the first silicon oxide layer 310 and undergo LPCVD processing (e.g., at a LPCVD process temperature set low enough to avoid damaging those components).

While the deuterated source LPCVD method of making the silicon nitride core 320 is described above, other methods of making a substantially hydrogen free or completely hydrogen free silicon nitride core may be used instead. Such methods include physical vapor deposition (“PVD”), such as sputtering, or atomic layer deposition (ALD) with a deuterated silane precursor. Thus, a very high temperature anneal (e.g., at a temperature above 1200 degrees Celsius) used to drive out hydrogen from silicon nitride cores deposited from a silane source is not required. Therefore, the silicon nitride core 320 may be formed above components, such as the silicon core 350, which can withstand temperatures below 1200 degrees Celsius, but which are damaged if subjected to a temperature above 1200 degrees Celsius.

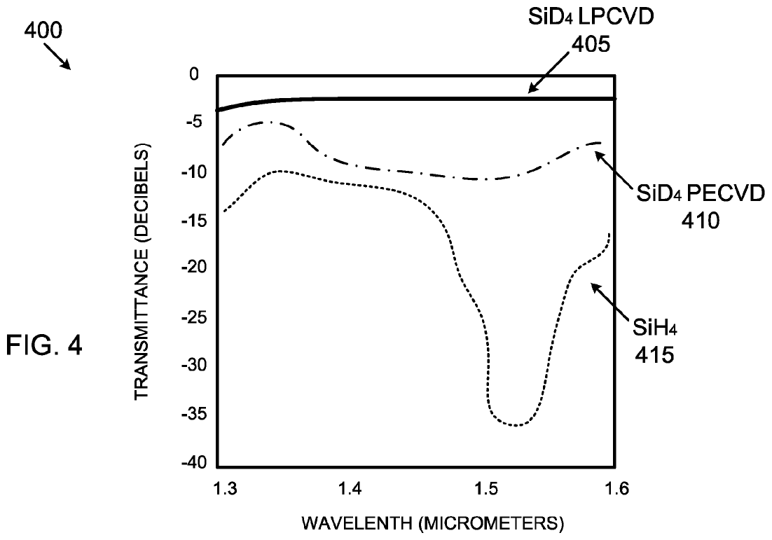

FIG. 4 shows a graph 400 of transmittance per wavelength, in accordance with some example embodiments. In the graph 400, the plot 415 corresponds to the transmittance of optical components (e.g., waveguides) formed using PECVD and a silane source (e.g., SiH₄). Plot 410 corresponds to the transmittance of optical components (e.g., waveguides) formed using PECVD with deuterated silane source. As shown, the transmittance of plot 410 is higher than plot 415, but a modern ultra-low loss optical systems may implement designs that use losses of lower than those shown by plot 410 (e.g., some designs may implement photonic systems that are designed to operate with losses below 5 decibels across some or all the operating wavelengths, e.g., 1.3-1.6 micrometers). The plot 405 shows an improved transmittance across wavelengths of optical components (e.g., waveguides) formed using LPCVD with a deuterated precursor (e.g., SiD₄ in this example).

The optical components formed using the approach of plot 405 can be formed FEOL, without plasma, and without high temperature anneals (e.g., the plot 405 corresponds to temperatures of processes below 1200 degrees Celsius and yields substantially hydrogen free or completely hydrogen free results).

In particular, the plot 405 shows transmittance in the 1500 to 1600 nm range of silicon nitride core above −5 dB, and is also more uniform than that of plot 410. The silicon nitride core formed by processes of plot 405 exhibits a maximum difference in loss value of 0.01 dB/cm or less (e.g., 0.001 to 0.01 dB/cm), between the range of wavelengths of 1520 nm and 1550 nm. Further, in one embodiment, the silicon nitride core formed from the processes of plot 405 may contain zero to less than 10¹⁷ hydrogen atoms per cm³, such as 10¹⁸ to 10¹⁶ hydrogen atoms per cm³.

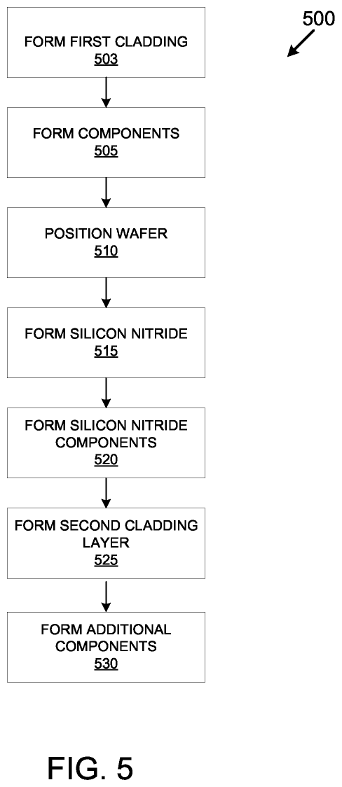

FIG. 5 shows a flow diagram of a method 500 for manufacturing hydrogen free silicon nitride waveguides, in accordance with some example embodiments. At operation 503, a first cladding layer is formed on a wafer (e.g., silicon wafer). At operation 505, form the one or more first components on the wafer. For example, at operation 505, a silicon waveguide core is formed in the embedded in a cladding layer (e.g., first silicon oxide layer 310, such as a buried silicon oxide (BOX) layer). It is appreciated that in some example embodiments, the steps of operations 503 and 505 can be performed in multiple sub-steps together (e.g., forming a first portion of the first cladding layer while embedding one or more first components in the first cladding layer).

At operation 510, the wafer is positioned in a chamber (e.g., chamber 203, such as positioned in a vertical wafer stack of a LPCVD furnace).

At operation 515, a silicon nitride layer is formed on the wafer using low-pressure chemical vapor deposition (LPCVD). In some example embodiments, the silicon nitride layer is formed with the chamber at a temperature between 750° C. and 1150°° C. (e.g., between 800° C. and 1150° C., or between 750°° C. to 850° C., to avoid harm to one or more semiconductor components in the first cladding layer). In some example embodiments, the silicon nitride layer is formed in the chamber at a pressure of 200 milliTorr. In some example embodiments, deuterated precursors are implemented to result in a silicon nitride devices (e.g., waveguides) that are substantially or completely hydrogen free. In some example embodiments, at operation 515, the silicon nitride layer is formed from a deuterated nitrogen source (e.g., deuterated ammonia) and deuterated silane source (e.g., deuterated DCS or SiD₄).

At operation 520, one or more silicon nitride components are formed from the silicon nitride layer. For example, the silicon nitride layer can be formed into waveguides by photolithography and etching, or other types of processing as discussed above.

At operation 525, a second cladding layer is formed on the silicon nitride layer. For example, at operation 525, the second silicon oxide layer 330 is applied to the silicon nitride core 320.

At operation 530, one or more additional components are formed over the wafer. For example, the one or more components integrated in the wafer structure at 530 may be components such as electrical transistors or other circuitry components that are not compatible with the temperature range used for the LPCVD operations of operation 515.

Example embodiments include: In one general example, an example method may include providing a first portion of a cladding located over a substrate. The method may also include forming a silicon nitride core over the first portion of the cladding using a deuterated silane source in a low-pressure chemical vapor deposition (LPCVD) process. The method may further include forming a second portion of the cladding over the silicon nitride core. Other embodiments of this aspect include corresponding computer systems, apparatus, and computer programs recorded on one or more computer storage devices, each configured to perform the actions of the methods.

Implementations may include one or more of the following features. The method where the LPCVD process is conducted at a temperature between 800 degrees Celsius and 1150 degrees Celsius without using a plasma. The method where the deuterated silane source may include a SiD₄ gas. The method may include using an ammonia source gas in addition to the SiD₄ gas during the LPCVD process to form the silicon nitride core. The method where forming the silicon nitride core may include depositing a silicon nitride layer using the LPCVD process and patterning the silicon nitride layer into the silicon nitride core. The method where the first portion of the cladding may include a first silicon oxide layer located over the substrate. The method may include a semiconductor component located over the substrate. The method where the semiconductor component may include second waveguide having a silicon core embedded in the first silicon oxide layer and located below the silicon nitride core. The method where the silicon core extends non-parallel relative to the silicon nitride core. The method where the forming the second portion of the cladding may include depositing a second silicon oxide layer over the silicon nitride core after patterning the silicon nitride layer. The method where the silicon nitride core exhibits a maximum difference in loss value between wavelengths of 1520 nm and 1550 nm of 0.01 dB/cm or less. The method where the silicon nitride core exhibits an average loss value between wavelengths of 1500 nm and 1600 nm of 0.2 dB/cm or less. Method where: the silicon nitride core contains a deuterium concentration detectable by Fourier transform infrared spectroscopy; and the silicon nitride core is completely hydrogen free or contains a hydrogen concentration below detection limit of at least one of electron energy loss spectroscopy, X-ray diffraction or secondary-ion mass spectrometry. Implementations of the described techniques may include hardware, a method or process, or a computer tangible medium.

In one general aspect, a waveguide structure may include a silicon nitride core. The waveguide structure may also include a cladding surrounding the silicon nitride core, the cladding having a lower refractive index than the silicon nitride core. The waveguide structure may in addition include the silicon nitride core contains a deuterium concentration detectable by Fourier transform infrared spectroscopy. The waveguide structure may moreover include the silicon nitride core is completely hydrogen free or contains a hydrogen concentration below detection limit of at least one of electron energy loss spectroscopy, X-ray diffraction or secondary-ion mass spectrometry. The waveguide structure may also include the silicon nitride core exhibits at least one of a maximum difference in loss value between wavelengths of 1520 nm and 1550 nm of 0.01 dB/cm or less, or an average loss value between wavelengths of 1500 nm and 1600 nm of 0.2 dB/cm or less. Other embodiments of this aspect include corresponding computer systems, apparatus, and computer programs recorded on one or more computer storage devices, each configured to perform the actions of the methods.

Implementations may include one or more of the following features. The waveguide structure where the cladding may include a silicon oxide cladding. The waveguide structure where the silicon nitride core has a height of 200 nm to 4000 nm, and a width of 200 nm to 4000 nm.

In one general example, an optical device comprises a substrate; and a semiconductor component located between the substrate and a silicon nitride core. The optical device with the semiconductor component may include a second waveguide having a silicon core embedded in a second cladding. non-parallel relative to the silicon nitride core. Optical device where the second cladding may include a silicon oxide layer which functions as the second cladding and as a lower portion of the cladding of the silicon nitride core.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen to best explain the principles underlying the claims and their practical applications, to thereby enable others skilled in the art to best use the embodiments with various modifications as are suited to the particular uses contemplated.

It is also understood that the examples and embodiments described herein are for illustrative purposes only and that various modifications or changes in light thereof will be suggested to persons skilled in the art and are to be included within the spirit and purview of this application and scope of the appended claims.

It will be understood that, although the terms first, second, etc. are, in some instances, used herein to describe various elements, these elements should not be limited by these terms. These terms are used only to distinguish one element from another. The terminology used in the description of the various described embodiments herein is for the purpose of describing embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “if” is, optionally, construed to mean “when” or “upon” or “in response to determining” or “in response to detecting” or “in accordance with a determination that,” depending on the context.

What is claimed is:

1. A method of making a waveguide, comprising:
providing a first portion of a cladding located over a substrate;
forming a silicon nitride core over the first portion of the cladding using a deuterated silane source in a low-pressure chemical vapor deposition (LPCVD) process; and
forming a second portion of the cladding over the silicon nitride core.

2. The method of claim 1, wherein the LPCVD process is conducted at a temperature between 750 degrees Celsius and 850 degrees Celsius without using a plasma.

3. The method of claim 1, wherein:
the substrate is located a furnace and the LPCVD process is conducted in the furnace;
a semiconductor device is embedded in the first portion of the cladding and the semiconductor device is damaged by temperatures higher than 850 degrees Celsius; and
forming the silicon nitride core comprises maintaining the temperature of the furnace below the 850 degrees Celsius.

4. The method of claim 1, wherein the deuterated silane source comprises deuterated dichlorosilane gas.

5. The method of claim 1, wherein the deuterated silane source comprises SiD₄ gas.

6. The method of claim 5, further comprising using an ammonia source gas in addition to the SiD₄ gas during the LPCVD process to form the silicon nitride core.

7. The method of claim 6, wherein the ammonia source gas comprises deuterated ammonia gas.

8. The method of claim 1, wherein forming the silicon nitride core comprises depositing a silicon nitride layer using the LPCVD process, and patterning the silicon nitride layer into the silicon nitride core.

9. The method of claim 8, wherein the first portion of the cladding comprises a first silicon oxide layer located over the substrate.

10. The method of claim 9, further comprising a semiconductor component located over the substrate.

11. The method of claim 10, wherein the semiconductor component comprises at least one or more of: a heat sensor, a heater, a phase shifter, or a barium titanate-based semiconductor component.

12. The method of claim 10, wherein the semiconductor component comprises a component formed from barium titanate.

13. The method of claim 10, wherein the semiconductor component comprises second waveguide comprising a silicon core embedded in the first silicon oxide layer and located below the silicon nitride core.

14. The method of claim 13, wherein the silicon core extends non-parallel relative to the silicon nitride core.

15. The method of claim 9, wherein the forming the second portion of the cladding comprises depositing a second silicon oxide layer over the silicon nitride core after patterning the silicon nitride layer.

16. The method of claim 1, wherein the silicon nitride core exhibits a maximum difference of loss of 0.01 dB/cm or less, between wavelengths in a range of 1520 nm and 1550 nm.

17. The method of claim 1, wherein the silicon nitride core exhibits an average loss value between wavelengths of 1500 nm and 1600 nm of 0.2 dB/cm or less.

18. The method of claim 1, wherein:
the silicon nitride core contains a deuterium concentration detectable by Fourier transform infrared spectroscopy; and
the silicon nitride core is completely hydrogen free or contains a hydrogen concentration below detection limit of at least one of electron energy loss spectroscopy, X-ray diffraction or secondary-ion mass spectrometry.

19. A waveguide, comprising:
a silicon nitride core; and
a cladding surrounding the silicon nitride core, the cladding having a lower refractive index than the silicon nitride core,
wherein:
the silicon nitride core contains a deuterium concentration detectable by Fourier transform infrared spectroscopy;
the silicon nitride core is completely hydrogen free or contains a hydrogen concentration below detection limit of at least one of electron energy loss spectroscopy, X-ray diffraction or secondary-ion mass spectrometry; and
the silicon nitride core exhibits a maximum difference in loss value between wavelengths of 1520 nm and 1550 nm of 0.01 dB/cm or less.

20. The waveguide of claim 19, wherein the cladding comprises a silicon oxide cladding.

21. The waveguide of claim 19, wherein the silicon nitride core has a height of 200 nm to 4000 nm, and a width of 200 nm to 4000 nm.

22. An optical device, comprising:
the waveguide of claim 19;
a substrate; and
a semiconductor component located between the substrate and the silicon nitride core.

23. The optical device of claim 22, wherein the semiconductor component comprises a second waveguide comprising a silicon core embedded in a second cladding.

24. The optical device of claim 23, wherein the silicon core extends non-parallel relative to the silicon nitride core.

25. The optical device of claim 23, wherein the second cladding comprises a silicon oxide layer which functions as the second cladding and as a lower portion of the cladding of the silicon nitride core.
